(19) United States
(12) Patent Application Publication
(10) Pub. No.: US 2023/0007807 A1
(43) Pub. Date: Jan. 5, 2023

(54) HEAT DISSIPATION DEVICE FOR ELECTRONIC COMPONENT

(71) Applicant: Valeo Siemens eAutomotive (Shenzhen) Co., Ltd., Shenzhen (CN)

(72) Inventors: Ronghui Li, Shenzhen (CN); Gongyuan Qu, Shenzhen (CN); Qingqing Liu, Shenzhen (CN)

(73) Assignee: Valeo Siemens eAutomotive (Shenzhen) Co., Ltd., Shenzhen (CN)

(21) Appl. No.: 17/782,537

(22) PCT Filed: Dec. 4, 2020
(86) PCT No.: PCT/IB2020/061487

§ 371 Date: Jun. 3, 2022

(30) Foreign Application Priority Data
Dec. 6, 2019 (CN) 201911244807.9

(51) Int. Cl. H05K 7/20

(52) U.S. Cl. CPC H05K 7/2049; H05K 7/209

(57) ABSTRACT

A heat dissipation device (2) for an electronic component is disclosed. The heat dissipation device includes a heat dissipating component (20) disposed on a first side of the electronic component (1); at least one elastic element (30) arranged on a second side of the electronic component (1) opposite the first side; a pressure plate (40) arranged such that the at least one elastic element (30) is located between the pressure plate (40) and the electronic component (1), the pressure plate (40) being connected to a fixed structure to apply pressure to the electronic component (1) via the at least one elastic element (30) in the direction of the heat dissipating component (20). An AC-DC converter or a DC-AC converter or a DC-DC converter comprising the heat dissipation device, and a motor vehicle comprising the above converter are also disclosed.

### TECHNICAL FIELD

The present invention relates to a heat dissipation device for an electronic component, such as a power electronic component fitted in a motor vehicle and used for an AC-DC converter or DC-AC converter or DC-DC converter, ensuring good thermal contact between the heat dissipation device and the electronic component.

### BACKGROUND ART

The operating temperature of an electronic component directly affects its own reliability. For example, in a power conversion circuit of an AC-DC converter or DC-AC converter or DC-DC converter, a power semiconductor device serves an important function, and the operating state thereof directly affects the reliability of operation of the entire apparatus. During use, the power semiconductor device will consume a portion of energy and convert this to heat, with the result that the power semiconductor device heats up, and the junction temperature rises. When the junction temperature exceeds a safety threshold, the current will increase sharply, and this may even cause a transistor to burn out. Thus, heat needs to be rapidly released to the surroundings by means of a heat dissipation device, to lower the operating temperature of the electronic component.

To ensure stable operation of the heat dissipation device, good thermal contact between the heat dissipation device and the electronic component needs to be maintained.

The use of a pressure plate and bolts to maintain contact between the heat dissipation device and the electronic component is known in the prior art. Specifically, the pressure plate is placed above the electronic component, and connected to a heat dissipation component by means of bolts at suitable positions, such that the electronic component is pressed tightly against the heat dissipation component. The most obvious drawback of this solution is that the rigid action force of the pressure plate is applied to the electronic component directly, and this might cause damage to the electronic component, which has a rather fragile structure.

The use of an elastic clip loaded with prestress to maintain contact between the heat dissipation device and the electronic component is also known in the prior art. Specifically, one end of the elastic clip is fixed to a fixed structure such as the heat dissipation component, and the other end applies an elastic action force to the electronic component, to bias the electronic component towards the heat dissipation component. Although this solution can avoid the application of a rigid action force to the electronic component, the elastic clip might develop fatigue as time passes under the action of a thermal load, causing a reduction in the elastic action force, with the result that stable contact between the heat dissipation component and the electronic component cannot be maintained.

### SUMMARY OF THE INVENTION

The object of the present invention is to at least overcome the abovementioned shortcomings in the prior art, maintaining good thermal contact between the heat dissipation device and the electronic component and reducing damage to the electronic component.

According to one aspect of the present invention, a heat dissipation device for an electronic component is proposed, wherein the heat dissipation device comprises: a heat dissipating component disposed on a first side of the electronic component; at least one elastic element arranged on a second side of the electronic component opposite the first side; a pressure plate arranged such that the at least one elastic element is located between the pressure plate and the electronic component, the pressure plate being connected to a fixed structure to apply pressure to the electronic component via the at least one elastic element in the direction of the heat dissipating component.

This configuration according to the present invention can avoid the direct application of a rigid action force to the electronic component, preventing the electronic component from experiencing local concentrated strain and thereby being damaged. In addition, since the pressure plate is connected to the fixed structure, as time passes, the elastic element can still apply a sufficient elastic action force to the electronic component, thereby forming stable and reliable thermal contact between the electronic component and the heat dissipating component.

In some embodiments, the electronic component is accommodated in a housing and electrically connected to a printed circuit board, wherein the fixed structure is a portion of the heat dissipating component or of the housing or of the printed circuit board.

In some embodiments, the pressure plate is firmly attached to the fixed structure. It is possible to use an almost permanent connection (e.g. welding, adhesive, riveting, etc.), or a removable connection with one or more fasteners (e.g. a screw, bolt, snap-fit connection, etc.).

In some embodiments, the at least one elastic element is plate-like with an arcuate shape overall, and comprises a top portion and two branch portions extending from the top portion.

In some embodiments, the at least one elastic element is a coil spring or an elastic pad.

In some embodiments, the pressure plate or the housing comprises a first positioning structure configured to cooperate with a second positioning structure of the at least one elastic element.

In some embodiments, the first positioning structure is a notch in the housing, the second positioning structure is a protrusion of the elastic element, and the protrusion of the elastic element is configured to be received in the notch of the housing.

In some embodiments, the first positioning structure is a recess formed in the pressure plate, the second positioning structure is the top portion of the elastic element, and the top portion is configured to be received in the recess of the pressure plate.

In some embodiments, the heat dissipation device further comprises a heat conducting layer arranged between the heat dissipating component and the electronic component.

In some embodiments, the heat dissipation device further comprises an electrical insulation sheet arranged between the at least one elastic element and the electronic component.

In some embodiments, the at least one elastic element is made of metal.

In some embodiments, the electronic component is a MOSFET.

According to another aspect of the present invention, an AC-DC converter or a DC-AC converter or a DC-DC converter comprising the heat dissipation device described above is proposed.

In some embodiments, the AC-DC converter or DC-AC converter or DC-DC converter comprises a housing, wherein the fixed structure is a portion of the housing, or the fixed structure is a portion of the heat dissipating component and the heat dissipating component is connected to the housing. Since the fixed structure is formed as a portion of the housing, or the fixed structure is formed as a portion of the heat dissipating component and the heat dissipating component is connected to the housing, the pressure plate is directly or indirectly fixed to the housing of the electronic apparatus. This is especially advantageous in the case where the electronic apparatus is an onboard electronic apparatus, such as an onboard AC-DC converter or DC-AC converter or DC-DC converter. This is because the running of a motor vehicle will be accompanied by vibration of the onboard electronic apparatus; such vibration might cause loosening of the thermal contact between the electronic component and the heat dissipating component, thereby weakening the heat dissipation effect. Having the pressure plate directly or indirectly fixed to the housing of the electronic apparatus enables the positioning of the pressure plate to be more reliable, thereby resisting the adverse effect of vibration on thermal contact more effectively.

According to another aspect of the present invention, a motor vehicle comprising the AC-DC converter or the DC-AC converter or the DC-DC converter described above is proposed.

### BRIEF DESCRIPTION OF THE DRAWINGS

Those skilled in the art will gain a better understanding of the content disclosed herein through the following drawings, which can reflect more clearly the advantages of the content disclosed herein. The drawings described here are merely intended to illustrate selected embodiments, not all possible embodiments, and are not intended to limit the scope of the content disclosed herein.

FIG. 1 is a perspective view of a heat dissipation device according to some embodiments of the present invention.

FIG. 2 is a perspective view of a heat dissipation device according to some embodiments of the present invention, wherein a pressure plate is not shown.

FIG. 3 is a sectional view of a heat dissipation device according to some embodiments of the present invention.

### DETAILED DESCRIPTION OF THE INVENTION

Preferred embodiments according to the present invention are explained in detail below in conjunction with the drawings. Those skilled in the art will gain further understanding of the characteristics and advantages of the present invention through the drawings and the corresponding explanatory text. Obviously, the embodiments described are some, not all, of the embodiments of the present invention. Generally, components of embodiments of the present invention that are described and shown in the drawings here may be arranged and designed in various configurations.

In the description of the present invention, a direction or position relationship indicated by terms like “top”, “bottom”, “up”, “down”, etc. is based on a direction or position relationship shown in a drawing, or is a direction or position relationship in which the invention product is usually placed when used, or is a direction or position relationship usually understood by those skilled in the art; it is intended only for convenience of description of the present invention and brevity of description, instead of indicating or implying that the device or component in question must have a specific direction or be constructed and operated in a specific direction, and therefore should not be construed as limiting the present invention.

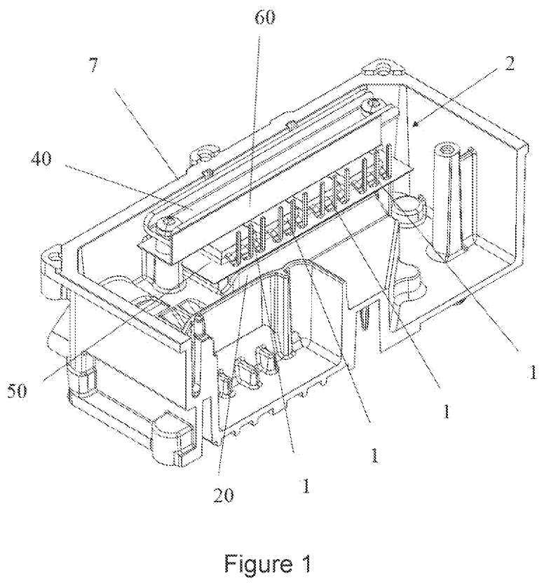

FIG. 1 shows a heat dissipation device 2 for an electronic component 1 according to the present invention. The electronic component 1 is a circuit component part of an electronic apparatus. In some embodiments, the electronic apparatus is for example an onboard AC-DC converter or DC-AC converter or DC-DC converter; these electronic apparatuses often generate large amounts of heat with high currents. However, it should be understood that the heat dissipation device 2 according to the present invention may also be used in other industrial fields including consumer electronics, household appliances, engineering machinery and electrical apparatuses.

As shown in FIG. 1, the electronic apparatus comprises a housing 7 and a printed circuit board (not shown) accommodated in the housing 7. For convenience of description, only part of the electronic apparatus is shown in FIG. 1. At least one electronic component 1 is electrically connected to the printed circuit board by means of pins for example. In FIG. 1, the number of electronic components 1 is 4 for example. The electronic component 1 is for example a power semiconductor device, such as a MOSFET, which during use will consume a portion of energy and convert this to a large amount of heat, with the result that the electronic component 1 heats up, and the junction temperature rises. For this purpose, at least one electronic component 1 shall be provided with a heat dissipation device 2, as described in detail below.

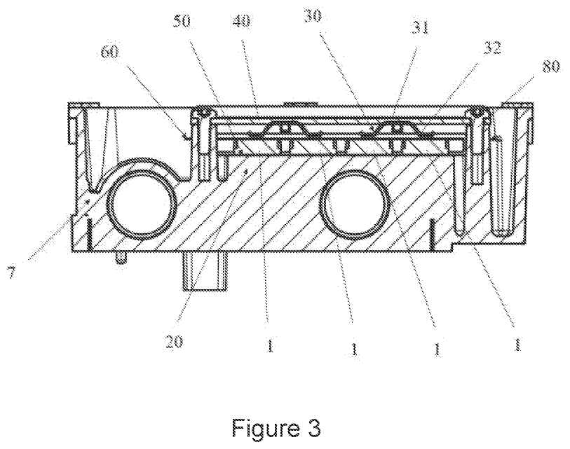

The heat dissipation device 2 comprises a heat dissipating component 20, also called a heat sink, arranged at a lower side of the electronic component 1. The heat dissipating component 20 can undergo heat exchange with the electronic component 1 and absorb the heat generated by the electronic component 1 during operation, to lower the temperature of the electronic component 1. In some embodiments, the heat dissipating component 20 is formed as a portion of the housing 7, as shown in FIG. 3. In other embodiments, the heat dissipating component 20 and the housing 7 are formed as separate components.

The heat dissipation device 2 may comprise a heat conducting layer 50 arranged between the heat dissipating component 20 and the electronic component 1, to promote heat exchange between the heat dissipating component 20 and the electronic component 1.

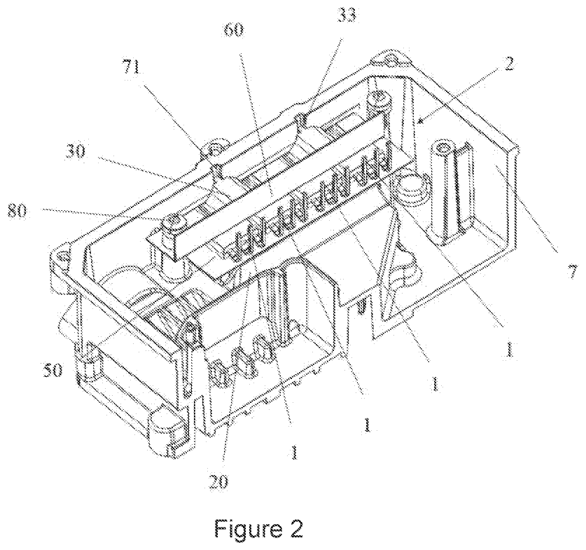

As best shown in FIGS. 2 and 3, the heat dissipation device 2 comprises at least one elastic element 30, arranged at an upper side of the electronic component 1, i.e. at the side opposite the heat dissipating component 20.

As best shown in FIGS. 1 and 3, the heat dissipation device 2 further comprises a pressure plate 40, arranged at an upper side of the at least one elastic element 30, such that the at least one elastic element 30 is held between the pressure plate 40 and the at least one electronic component 1. The pressure plate 40 is connected to a fixed structure. The at least one elastic element 30 is compressed between the pressure plate and the at least one electronic component 1, thereby applying pressure to the electronic component 1 in the direction of the heat dissipating component 20.

This configuration according to the present invention can avoid the direct application of a rigid action force to the electronic component 1, preventing the electronic component 1 from experiencing local concentrated strain and thereby being damaged. In addition, since the pressure plate 40 is connected to the fixed structure, as time passes, the elastic element 30 can still apply a sufficient elastic action force to the electronic component 1, thereby forming stable and reliable thermal contact between the electronic component 1 and the heat dissipating component 20.

In some embodiments, the fixed structure may be a portion of the printed circuit board.

In some embodiments, the fixed structure may be a portion of the housing 7 of the electronic apparatus.

In some embodiments, the fixed structure may be a portion of the heat dissipating component 20.

In some embodiments, the fixed structure may be a portion of the heat dissipating component 20, and the heat dissipating component 20 may be connected to the housing 7 of the electronic apparatus.

The fixed structure is a portion of the housing 7 of the electronic apparatus or the fixed structure is a portion of the heat dissipating component 20, and the heat dissipating component 20 may be connected to the housing 7 of the electronic apparatus. In these two configurations, the pressure plate 40 is directly or indirectly fixed to the housing 7 of the electronic apparatus. This is especially advantageous in the case where the electronic apparatus is an onboard electronic apparatus, such as an onboard AC-DC converter or DC-AC converter or DC-DC converter. The running of a motor vehicle will be accompanied by vibration of the onboard electronic apparatus; such vibration might cause loosening of the thermal contact between the electronic component 1 and the heat dissipating component 20, thereby weakening the heat dissipation effect. Having the pressure plate 40 directly or indirectly fixed to the housing 7 of the electronic apparatus enables the positioning of the pressure plate to be more reliable, thereby resisting the adverse effect of vibration on thermal contact.

In some embodiments, the pressure plate is firmly attached to the fixed structure. It is possible to use an almost permanent connection (e.g. welding, adhesive, riveting, etc.), or a removable connection with one or more fasteners (e.g. a screw, bolt, snap-fit connection, etc.). As shown in FIGS. 1 and 2, the pressure plate 40 is fixed to the fixed structure by means of screws 80, and the action force applied to the electronic component 1 by the at least one elastic element 30 can be adjusted by adjusting the screws 80.

In some embodiments (not shown), the elastic element is a coil spring, which is made of a metal material for example.

In some embodiments (not shown), the elastic element is an elastic pad, which is made of an elastic material for example.

In some embodiments, the elastic element is plate-like with an arcuate shape overall, and comprises a top portion 31 and two branch portions 32 extending from the top portion 31, as shown in FIGS. 2 and 3. The plate-like elastic element 30 is made of metal for example. The heat dissipation device 2 may comprise an electrical insulation sheet 60 arranged between the elastic element 30 and the electronic component 1. The top portion 31 of the plate-like elastic element 30 abuts the pressure plate 40; the branch portions 32 of the plate-like elastic element 30 are supported on the electronic component 1 via the electrical insulation sheet 60. As shown in FIG. 3, the electronic apparatus comprises four electronic components 1 and two plate-like elastic elements 30. Each plate-like elastic element 30 is allocated to two adjacent electronic components 1, with one branch portion 32 thereof being supported on one electronic component 1 via the electrical insulation sheet 60.

In some embodiments, the plate-like elastic element 30 and the pressure plate 40 are both made of metal, e.g. 301 stainless steel. The thickness of the plate-like elastic element 30 is in the range of 0.6 mm to 1 mm. The thickness of the pressure plate 40 is in the range of 2 mm to 3 mm. The plate-like elastic element and pressure plate in the above thickness ranges can supply a sufficient action force to the electronic component, to achieve reliable thermal contact between the electronic component and the heat dissipating component.

In some embodiments, the pressure plate 40 or the housing 7 comprises a first positioning structure configured to cooperate with a second positioning structure of the at least one elastic element 30; the elastic element 30 can thereby be held in place, so as to apply a stable elastic action force to the electronic component 1, and thereby ensure good thermal contact between the electronic component 1 and the heat dissipating component 20. In addition, the cooperation of the first positioning structure and second positioning structure also enables the elastic element and pressure plate to be fitted together more easily.

In some embodiments, as shown in FIG. 2, the first positioning structure is a notch 71 in the housing 7, and the second positioning structure is a protrusion 33 of the plate-like elastic element 30; the protrusion 33 of the plate-like elastic element 30 is configured to be received in the notch 71 of the housing 7. Thus, the position of the elastic element 30 can be held relative to the housing, and a mounting position can be quickly determined in the process of fitting the elastic element.

In some embodiments (not shown), the first positioning structure is a recess formed in the pressure plate 40, and the second positioning structure is the top portion 31 of the elastic element 30; the top portion 31 is configured to be received in the recess of the pressure plate 40. Thus, the position of the elastic element 30 can be held relative to the pressure plate, and since the pressure plate is fixed relative to the housing or the heat dissipating component, the elastic element is also not easy to move relative to the heat dissipating component, and can thereby apply a stable action force to the electronic component.

Of course, those skilled in the art will also be able to envisage other positioning structures to hold the elastic element in place. For example, in the case where the elastic element is a coil spring or elastic element, a receiving seat for the coil spring or elastic element may be provided in the pressure plate, the receiving seat being matched in shape to the coil spring or elastic element.

The heat dissipation device proposed in the present invention also advantageously simplifies manufacturing and assembly process steps. In prior art in which an elastic clip is used, in order to enable the elastic clip to apply a sufficient action force to the electronic component, it is often necessary to complete a process step of elastic clip deformation with the aid of an automatic press machine, and this is time-consuming and laborious. In the present invention, all of the assembly process steps can be completed at one workstation; all that need be done is to stack the heat conducting layer, electronic component, electrical insulation sheet, elastic element and pressure plate in sequence and then fix the pressure plate. The operation is simple and convenient, and there is no need for an additional installation apparatus to be introduced.

Further features of the present invention can be found in the claims, the drawings, and the description of the drawings. The features and feature combinations mentioned in the specification above and the features and feature combinations further illustrated in the drawings and/or shown independently in the drawings are not only used for the combinations that are respectively indicated, but also used in other combinations or independently used, without violating the scope of the present invention. Details of the present invention that are not explicitly shown and explained in the drawings but emerge and can be produced from explained details through independent feature combinations thus become included and disclosed. Thus, details and feature combinations that lack all of the features of the independent claims originally formed should also be regarded as being disclosed.

1. A heat dissipation device for an electronic component, the heat dissipation device comprising:
a heat dissipating component disposed on a first side of the electronic component;
at least one elastic element arranged on a second side of the electronic component opposite the first side;
a pressure plate arranged such that the at least one elastic element is located between the pressure plate and the electronic component, the pressure plate being connected to a fixed structure to apply pressure to the electronic component via the at least one elastic element in the direction of the heat dissipating component.

2. A heat dissipation device according to claim 1, wherein said electronic component is accommodated in a housing and electrically connected to a printed circuit board, and wherein said fixed structure is a portion of the heat dissipating component or of the housing or the printed circuit board.

3. A heat dissipation device according to claim 1, wherein the pressure plate is firmly attached to the fixed structure.

4. A heat dissipation device according to claim 1, wherein said at least one elastic element has generally an arcuate shape and comprises a top portion and two branch portions extending from the top portion.

5. A heat dissipation device according to claim 1, wherein the at least one elastic element is a coil spring or an elastic pad.

6. A heat dissipation device according to claim 2, wherein the pressure plate or the housing comprises a first positioning structure configured to cooperate with a second positioning structure of said at least one elastic element.

7. The heat dissipation device according to claim 6, wherein the first positioning structure is a notch in the housing, the second positioning structure is a protrusion of the elastic element, and the protrusion of the elastic element is configured to be received in the notch of the housing.

8. The heat dissipation device according to claim 6, wherein:
the at least one elastic element has generally an arcuate shape and comprises a top portion and two branch portions extending from the top portion, and
the first positioning structure is a recess formed in the pressure plate, the second positioning structure is the top portion of the elastic element, and the top portion is configured to be received in the recess of the pressure plate.

9. The heat dissipating device according to claim 1, further comprising: a heat conducting layer arranged between the heat dissipating component and the electronic component.

10. The heat dissipation device according to claim 1, further comprising: an electrical insulation sheet arranged between the at least one elastic member and the electronic component.

11. A heat dissipation device according to claim 4, wherein the at least one elastic element is made of metal.

12. A heat dissipation device according to claim 1, wherein the electronic component is a MOSFET.

13. An AC-DC converter or a DC-AC converter or a DC-DC converter comprising the heat dissipation device according to claim 1.

14. The AC-DC converter or DC-AC converter or DC-DC converter according to claim 13, wherein said AC-DC converter or DC-AC converter or DC-DC converter comprises a housing, and wherein the fixed structure is a portion of the housing, or the fixed structure is a portion of the heat dissipating component and the heat dissipating component is connected to the housing.

15. A motor vehicle comprising the AC-DC converter or the DC-AC converter or the DC-DC converter according to claim 13.
